(19) United States
(12) Patent Application Publication
(10) Pub. No.: US 2004/0168565 A1
(43) Pub. Date: Sep. 2, 2004

(54) Method and apparatus for reproducing digital data in a portable device

(75) Inventors: Atsushi Nagao, Fussa-shi (JP); Masaki Sakai, Hino-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA.

(21) Appl. No.: 10/786,101

(22) Filed: Feb. 26, 2004

(30) Foreign Application Priority Data
Feb. 27, 2003 (JP) 2003-050348

(51) Int. Cl. G10H 1/06; G10H 7/00; G10H 1/46; H03G 3/00

(52) U.S. Cl. 84/633

(57) ABSTRACT

A portable device has a portable telephone function and a music reproduction function. In a music reproduction mode, a dedicated unit receives music data from a memory and executes music reproduction processing. In addition, the dedicated unit generates vibrator vibration data based on which a vibrator output is provided in synchronism with the music reproduction. An audio output unit provides an audio output which is produced from a loudspeaker in accordance with an acoustic signal output from the dedicated unit. A peripheral output unit controls the driving of the vibrator in accordance with the vibrator vibration data output from the dedicated data.

### CROSS-REFERENCE TO RELATED APPLICATIONS

This application is based upon and claims the benefit of priority from prior Japanese Patent Application No. 2003-050348, filed Feb. 27, 2003, the entire contents of which are incorporated herein by reference.

### BACKGROUND OF THE INVENTION

1. Field of the Invention

The present invention relates to a portable terminal device such as a portable telephone device or a PDA, more particularly to a portable terminal device having a function of reproducing digital data (e.g., digital music data).

2. Description of the Related Art

An acoustic signal processing apparatus for reproducing acoustic signals and displaying them is known in the art. (Refer to Jpn. Pat. Appln. KOKAI Publication No. 11-126424, for example.)

In this type of acoustic signal processing apparatus, a digital signal processor (hereinafter referred to as a “DSP”) receives digital acoustic signals from a digital recording medium and executes the digital signal processing for reduction, including signal demodulation. Then, the DSP sends reproduced acoustic signals to a loudspeaker.

A microprocessor (CPU), which is a main control device of the apparatus, receives demodulated acoustic signals from the DSP and detects the volume level of them. Subsequently, the microprocessor controls a display device to show a volume level that is synchronous to the acoustic signals being reproduced.

The acoustic signal processing apparatus of the above configuration enables a user to watch the volume level variations on the display device while listening to the music. Therefore, the user can enjoy the music not only acoustically but also visually.

A reproduction apparatus for reproducing audio data is also known in the art. (Refer to Jpn. Pat. Appln. KOKAI Publication No. 2000-347696, for example.)

In the reproduction apparatus, a DSP receives encrypted audio data from a memory card, then decrypts the audio data, and then sends the decrypted audio signals to a loudspeaker.

A controller, provided outside the reproduction apparatus, controls a display device to show additional information regarding the audio data. The user can therefore watch the additional information while listening to the audio signals output from the loudspeaker.

Furthermore, a communication terminal apparatus capable of controlling the vibration level of a vibrator in response to a melody signaling an incoming call, is known in the art. (Refer to Jpn. Pat. Appln. KOKAI Publication No. 2002-16672, for example.)

In the communication terminal apparatus, a CPU, which is a main control device of the apparatus, controls the vibration level of the vibrator. The user can feel the vibrator change in vibration level while listening to the melody output from a loudspeaker.

In the apparatuses described above, the DPS executes the high-speed digital signal processing required for the reproduction of acoustic signals. The CPU, which is the main control device, controls displaying the volume level (which is additional information on acoustic signals) and takes charge of an incidental function, such as the level control of the vibrator.

In general, the CPU, which is the main control device, frequently executes various kinds of control, in addition to the display of the volume level and the control of the vibration level of the vibrator. Since interrupt processing has to be frequently carried out, the workload of the CPU is inevitably heavy. The CPU therefore requires high performance especially when it is incorporated in a sophisticated portable terminal device. In addition, since the power consumption increases in accordance with an increase in the speed of the CPU, the apparatus is inevitably costly.

### BRIEF SUMMARY OF THE INVENTION

In accordance with an aspect of the present invention, there is a provided a portable device which is configured to attain a function incidental to the reproduction of digital data without increasing the workload of a CPU serving as a main control device. The portable device comprises: a memory configured to store digital data; a first output unit configured to provide an output in accordance with a reproduction signal obtained by subjecting the digital data to reproduction processing; a second output unit configured to provide an output in accordance with incidental data obtained by subjecting the digital data to the reproduction processing; a central control unit configured to execute control operations other than the reproduction processing; and a dedicated unit configured to generate the reproduction signal and the incidental data by receiving the digital data from the memory and executing the reproduction processing with respect to the digital data, the dedicated unit supplying the reproduction signal and the incidental data to the first and second output units, respectively.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a block diagram illustrating the major portion of a portable device according to the first embodiment of the present invention.

FIG. 2 shows a modification of the first embodiment.

FIG. 3 is a flowchart illustrating how the portable device of the first embodiment operates.

FIG. 4 is a flowchart illustrating how a DSP employed in the first embodiment operates.

FIG. 5 is a flowchart illustrating how a DSP employed in the modification of the first embodiment operates.

FIG. 6 is a block diagram illustrating the major portion of a portable device according to the second embodiment of the present invention.

FIG. 7 is a block diagram illustrating the major portion of a portable device according to the third embodiment of the present invention.

FIG. 8 is a block diagram illustrating the major portion of a portable device according to the fourth embodiment of the present invention.

FIG. 9 is a flowchart illustrating how the portable device of the third embodiment operates.

### DETAILED DESCRIPTION OF THE INVENTION

Embodiments of the present invention will now be described.

### First Embodiment

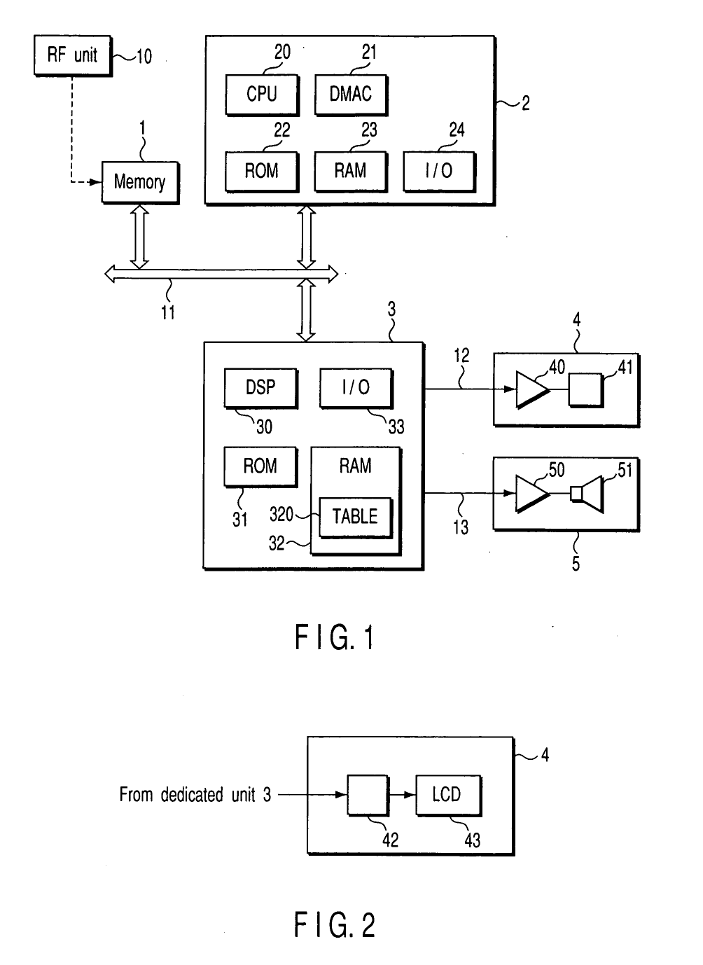

FIG. 1 is a block diagram illustrating the major portion of a portable device according to the first embodiment.

The first embodiment is an embodiment wherein the present invention is applied to a portable telephone device or a PDA (personal digital assistance). In the descriptions below, the portable telephone device will be referred to as an example of the portable device.

As shown in FIG. 1, the portable telephone device comprises a memory 1, a central control unit 2, a dedicated unit 3, a peripheral output unit 4, an audio output unit 5, and a bus 11.

The memory 1, the central control unit 2 and the dedicated unit 3 are connected to the bus 11, and data is transferred between them.

The central control unit 2 serves as a main control unit of the portable telephone device. The central control unit 2 includes a microprocessor (CPU) 20, a DMAC (direct memory access controller) 21, a ROM (read only memory) 22, a RAM (random access memory) 23 and an I/O (input/output) unit 24.

The CPU 20 performs various control operations by executing the programs stored in the ROM 22. The DMAC 21 of the central control unit 2 serves as a bus master. The central control unit 2 manages the data on the bus 11 and controls the data transfer performed between the memory and the dedicated unit 3.

The memory 1 is a RAM that stores music data (compressed data), which will be described later. The memory 1 stores, for example, music data that is downloaded from the Internet when the central control unit 2 drives an RF unit 10.

The memory 1 is used as a work memory area of the central control unit 2 as well. The memory 1 may be realized as an IC memory incorporated in the portable device or as a memory card removable from the portable device.

The dedicated unit 3 includes a digital signal processor (DSP) 30, a ROM 31, a RAM 32 and an I/O unit 33. The dedicated unit 3 is a dedicated LSI module that uses the DSP 30 as a main element. The dedicated LSI module executes digital signal processing for the music data stored in the memory 1, and also executes reproduction processing for generating acoustic signals for music reproduction (the reproduction processing includes expansion processing by which compressed data is restored to its original data).

The dedicated unit 3 executes not only the reproduction processing of music data but also incidental processing, by which the peripheral output unit 4 is executed.

The ROM 31 stores programs for the DSP 30. The RAM 32 is a work memory including table information 320, which is required for the incidental processing of the first embodiment. The I/O unit 33 includes a D/A converter and outputs acoustic signals 13 (which are reproduction signals) and incidental data signals 12 (which are generated as a result of the incidental processing).

In the first embodiment, the incidental data signals 12 are vibrator intensity data signals used for controlling the intensity level (vibration level) of a vibrator 41.

The peripheral output unit 4 includes this vibrator 41 along with its driver 40. The driver 40 drives the vibrator 41 in accordance with the vibrator intensity data signals 12 output from the dedicated unit 3.

The audio output unit 5 includes a loudspeaker 51 (from which music is output) and an amplifier 50. The amplifier 50 drives the loudspeaker 51 in accordance with the acoustic signals output from the dedicated unit 3.

### Operation of the First Embodiment

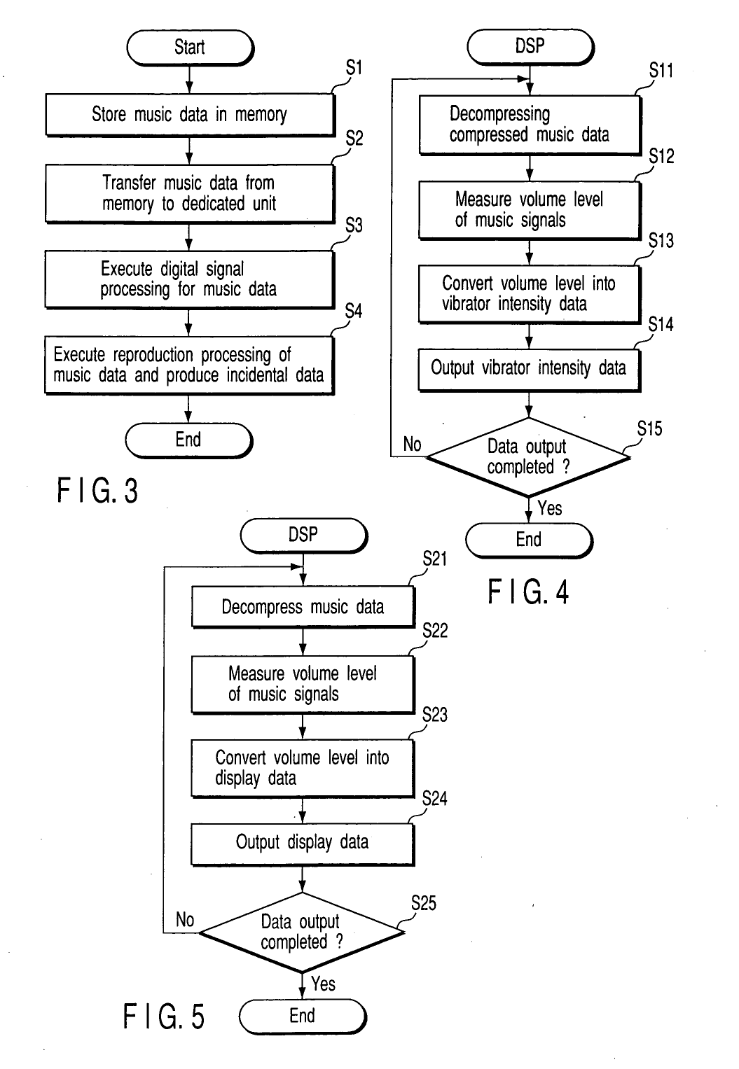

FIG. 3 is a flowchart illustrating how the portable telephone device of the first embodiment performs operations not related to the communicating function, namely the reproduction processing of music data and the operation incidental to that processing.

Let us assume that the CPU 20 of the portable telephone device of the first embodiment controls the RF unit 10 in response to an instruction from the user, and the music data the user designates is downloaded from the Internet to the memory 1.

The memory 1 stores compressed music data (acoustic data) (Step S1).

The DMAC 21 of the central control unit 2 operates as a bus master. It reads compressed music data out of the memory 1 and sends it to the dedicated unit 3 (Step S2).

The dedicated unit 3 executes digital signal processing for the music data it receives (Step S3). To be more specific, the DSP 30 generates acoustic signals 13 by executing the reproduction processing of the music data. In addition, the DSP 30 produces incidental data (which is vibrator intensity data in the first embodiment) from the music data and outputs incidental data signals (vibrator intensity data signals) 12 (Step S4).

A description will now be given with reference to the flowchart of FIG. 4 as to how the DSP 30 of the dedicated unit 3 operates.

The DSP 30 executes reproduction processing. This reproduction processing includes decompressing the compressed music data to obtain the original music data (music signals) (Step S11). By use of the D/A converter of the I/O unit 33, the DSP 30 produces analog acoustic signals 13 and sends them to the audio output unit 5.

The acoustic signals 13 are amplified by the amplifier 50 of the audio output unit 5 and then output from the loudspeaker 51. In this manner, the user can enjoy listening to the music which is reproduced from the music data downloaded from the Internet and which is output from the loudspeaker 51 (including an earphone).

The DSP 30 measures the volume level of the reproduced music signals (Step S12). To be more specific, the DSP 30 keeps measuring the volume level during a predetermined period of time (e.g., 100 ms) and detects the average value (or maximal value) of the volume level.

Then, the DSP 30 converts the measured volume level (i.e., the average or maximal value) into vibrator intensity data (i.e., incidental data) by referring to the table information 320 stored in the RAM 32 (Step S13). It should be noted that the table information 320 of the RAM 32 associates volume levels with vibrator intensities (vibration levels).

By use of the D/A converter of the I/O unit 33, the DSP 30 obtains analog vibrator intensity signals 12 and sends them to the peripheral output unit 4 (Step S14). The analog vibrator intensity signals 12 are, for example, voltage signals.

The peripheral output unit 4 vibrates the vibrator 41 in accordance with the output signals 12, and the vibration that corresponds to the volume level of the music being output is transmitted to the user.

The peripheral output unit 4 is not limited to the configuration described above. It may include a D/A converter which receives digital vibration intensity data from the dedicated unit 3 and which converts it into voltage signals used for driving the vibrator 41.

One piece of music is reproduced by repeating Steps S11 to S14 described above. At the end of the music reproduction, the processing by the DSP 30 of the dedicated unit 3 is ended (“YES” of Step S15).

The portable telephone device of the first embodiment enables the user to download music data from the Internet and acoustically enjoy the music reproduced from the loudspeaker 51. In addition, the vibration from the vibrator 41 of the peripheral output unit 4 is transmitted to the user, and the intensity of this vibration varies in synchronism with changes in the volume level of the music. The user can therefore enjoy the vibration when the music is being reproduced.

The dedicated unit 3 is not limited to the one that measures the volume level of the music data. Instead of this configuration, the dedicated unit 3 may measure frequency components of the music data and convert the frequency components into vibrator intensity data.

The portable device of the first embodiment was described as a portable telephone device incorporating both the audio output unit 5 and the peripheral output unit 4, but is not limited to this. That is, one or both of the audio output unit 5 and peripheral output unit 4 may be incorporated in an external acoustic device. Where this structure is adopted, the portable device of the embodiment and the external acoustic device constitute a music reproduction system with satisfactory sound effects.

Where the CPU 20 is sophisticated and the central control unit 2 has extra processing power, the DMAC 21 is not necessarily required. In other words, the CPU 20 may control the dedicated unit 3 to transfer the compressed music data from the memory 1.

As described above, the reproduction processing of music data and the incidental processing (the control of the peripheral output unit 4, namely vibration output control) are executed by the dedicated unit 3 using the DSP 30 as its major element.

On the other hand, the central control unit 2 merely transfers music data from the memory 1 to the dedicated unit 3. Since the central control unit 2 does not have to perform the music reproduction processing or its incidental processing, the workload on the central control unit 2 can be remarkably reduced. In other words, the number of interrupt operations the control unit 2 has to perform for the music reproduction processing and the incidental processing can be significantly reduced. Hence, the other control operations can be executed at high speed, and the processing efficiency enhanced.

### Modification

FIGS. 2 and 5 illustrate a modification of the first embodiment.

As shown in FIG. 2, the peripheral output unit 4 according to the modification is a display device comprising a liquid crystal display (LCD) 43 and a display driver 42. Since the other configurations of the modification are similar to the configurations shown in FIG. 1, a description of them will be omitted.

An operation of the DSP 30 of the dedicated unit 3 will now be described with reference to the flowchart shown in FIG. 5.

First of all, the DSP 30 executes reproduction processing that includes decompressing compressed music data (Step S21). The reproduction processing is executed in a similar manner to that of Steps S11 and S12 shown in FIG. 4. In addition, the DSP 30 measures the volume level of the music signals (Step S22).

Then, the DSP 30 converts the measured volume level into display data (i.e., incidental data) by referring to the table information 320 stored in the RAM 32 (Step S23). It should be noted that the table information 320 of the RAM 32 associates volume levels with analyzer display data.

By use of the D/A converter of the I/O unit 33, the DSP 30 obtains display data signals 12 and sends them to the peripheral output unit 4 (Step S24).

The peripheral output unit 4 controls the LCD 43 to display an analyzer that is proportional to the volume level of the music signals.

The peripheral output unit 4 may include an LED in place of the LCD 43. In this case, the LED blinks in accordance with the volume level.

The dedicated unit 3 is not limited to the one that measures the volume level of the music data. Instead of this configuration, the dedicated unit 3 may measure frequency components of the music data and convert the frequency components into display data displayed as a spectrum analyzer.

As described above, the portable telephone device of the present modification enables the user to download music data from the Internet and acoustically enjoy the music reproduced from the loudspeaker 51 of the audio output unit 5. In addition, the user can visually confirm the analyzer the peripheral output unit 4 displays in synchronism with the volume level of the music.

### Second Embodiment

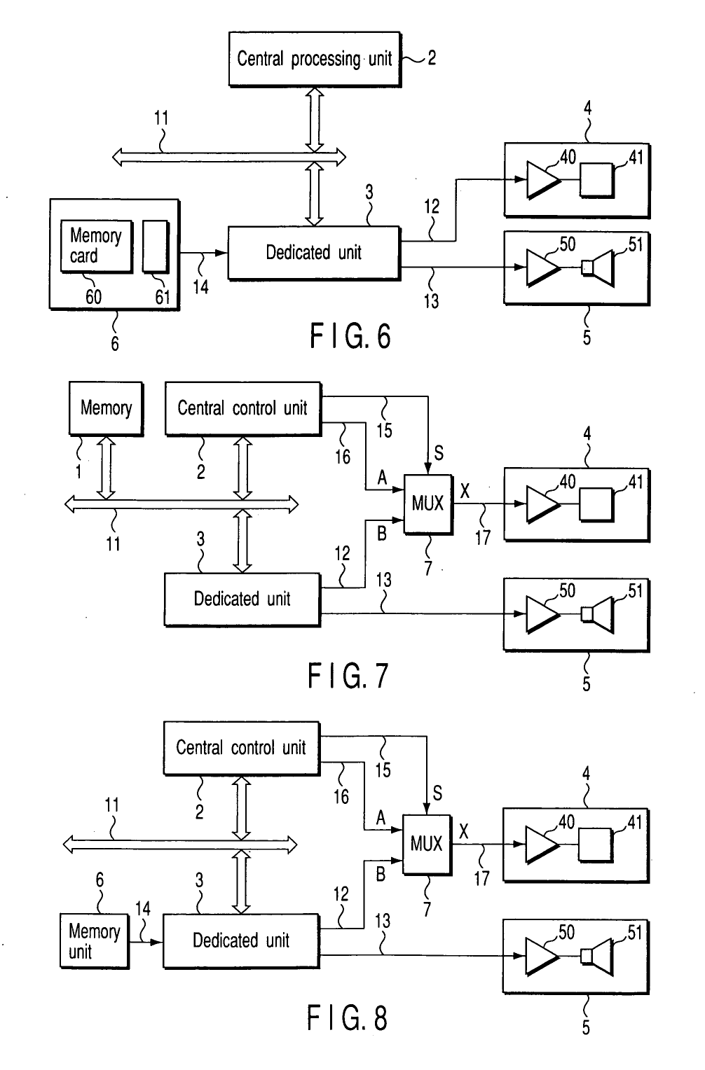

FIG. 6 is a block diagram illustrating the major portion of a portable device according to the second embodiment of the present invention. In the description below, reference will be made to how the second embodiment differs from the first embodiment. In FIG. 2, the same reference numerals as used in FIG. 1 denote similar or corresponding structural elements, and a description of such elements will be omitted. For example, the central control unit 2 and the dedicated unit 3 have internal structures similar to those described with reference to FIG. 1, and a description of them will be omitted.

As shown in FIG. 6, the dedicated unit 3 of the second embodiment is connected to a memory unit 6 and manages the memory card 60 of the memory unit 60.

The memory card 60 is detachable from the memory unit 6. In addition to this memory card 60, the memory unit 6 comprises an interface 61 (including a card slot). The memory card 60 stores music data compressed beforehand.

A description will be given as to how the portable telephone device of the second embodiment reproduces music data.

First of all, the central control unit 2 activates the dedicated unit 3 in response to an input designation from the user. The dedicated unit 3 reads compressed music data out of the memory card through the interface 61.

As in the first embodiment, the dedicated unit 3 reproduces acoustic signals 13 from the music data and sends the acoustic signals 13 to an audio output unit 5. Simultaneous with this reproduction processing, the dedicated unit 3 measures the volume levels of the music data, converts the volume levels into vibrator intensity data signals 12, and sends the vibrator intensity data signals 12 to a peripheral output unit 4.

Therefore, the user can listen to the music and simultaneously enjoy the vibration transmitted from the vibrator 41.

In the portable telephone device of the second embodiment, the dedicated unit 3 also reads music data out of the memory card 60. Since the central control unit 2 does not transfer music data to the dedicated unit 3, the workload of the central control unit 2 is further decreased.

### Third Embodiment

FIG. 7 is a block diagram illustrating the major portion of a portable device according to the third embodiment of the present invention.

In the description below, reference will be made to how the third embodiment differs from the first embodiment. In FIG. 7, the same reference numerals as used in FIG. 1 denote similar or corresponding structural elements, and a description of such elements will be omitted. For example, the central control unit 2 and the dedicated unit 3 have internal structures similar to those described with reference to FIG. 1, and a description of them will be omitted.

The portable telephone device of the third embodiment comprises a multiplexer (MUX) 7 connected to both the central control unit 2 and the dedicated unit 3. At input terminal A, the multiplexer 7 receives an output signal 16 supplied from the I/O unit 24 of the central control unit 2. The output signal 16 is a control signal which drives the vibrator 41 when the portable telephone device has an incoming call or when the portable telephone generates an alarm.

At input terminal B, the multiplexer 7 receives an output signal 12 supplied from the I/O unit 33 of the dedicated unit 3. As in the first embodiment, the output signal 12 drives the vibrator 41 in synchronism with the music reproduction.

At selector terminal S, the multiplexer 7 receives a selection signal 15 supplied from the I/O unit 24 of the central control unit 2. In accordance with the selection signal 15, the multiplexer 7 selects either the signal 16 received at input terminal A or the signal 12 received at input terminal B. The selected signal is output from the output terminal X of the multiplexer 7 and supplied to the peripheral output unit 4.

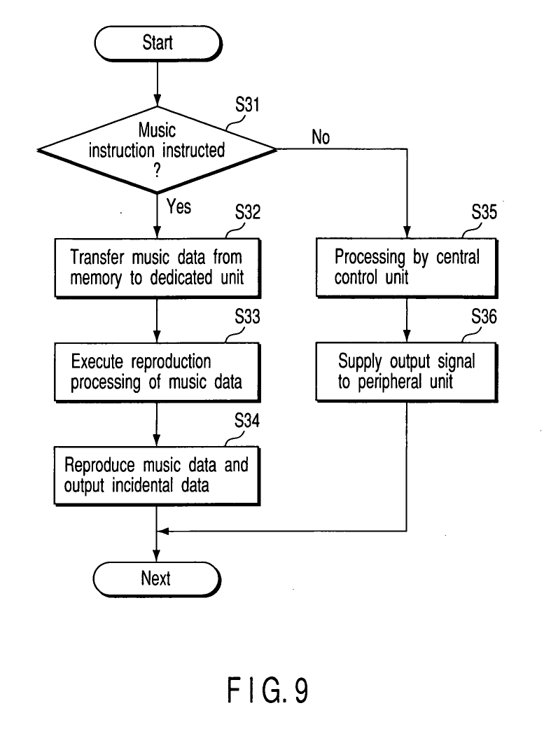

An operation of the portable telephone device of the third embodiment will now be described with reference to the flowchart shown in FIG. 9.

First of all, the central control unit 2 checks whether the reproduction of music data is instructed based on a user's input instruction. If this is the case, the central control unit 2 controls the I/O unit 24 to output a selection signal 15 for selecting input terminal B. The selection signal is supplied to selection terminal S of the multiplexer 7 (“YES” in Step S31).

The central control unit 2 reads compressed music data out of the memory 1 and sends it to the dedicated unit 3 (Step S32).

The dedicated unit 3 executes reproduction processing of the music data, thereby producing acoustic signals 13. On the other hand, the DSP 30 generates vibrator intensity data from the music data and outputs vibrator intensity data signals 12 (Steps S33 and S34).

The multiplexer 7 supplies the vibrator intensity data signals 12, which are received at input terminal, to the peripheral output unit 4. In the meantime, the audio output unit 5 amplifies the acoustic signals 13 supplied from the dedicated unit 3, and the amplified acoustic signals 13 are output from the loudspeaker 51.

In this manner, the user can enjoy listening to the music which is reproduced from the music data downloaded from the Internet and which is output from the loudspeaker 51 (including an earphone) of the portable telephone. As in the first embodiment, the vibration from the vibrator 41 of the peripheral output unit 4 is transmitted to the user, and the intensity of this vibration varies in synchronism with changes in the volume level of the music. The user can therefore enjoy the vibration when the music is being reproduced.

If the reproduction of music data is not instructed, the central control unit 2 controls the I/O unit 24 to output a selection signal 15 for selecting input terminal A. The selection signal 15 is supplied to selection terminal S of the multiplexer 7 (“NO” in Step S31).

If the portable telephone device receives a call or sounds an alarm, the central control unit 2 controls the I/O unit 24 to output a signal 16 for vibrating the vibrator 41 (Step S35).

The user feels the vibrator 41 vibrate and therefore recognizes that the portable telephone has received a call or is generating an alarm.

The portable telephone device of the third embodiment is advantageous in that the peripheral output unit 4 can be used not only for signaling an incoming call or an alarm but also as a vibrator that vibrates in accordance with the volume levels of the music data. Since the portable telephone device is small in size, it is undesirable to increase the number of structural components required. Since the vibrator of the third embodiment can be used not only for the original purpose (i.e., the indication of an incoming call or an alarm) but also as a vibrator that vibrates in accordance with the volume levels of the music data, the third embodiment is effective in preventing an increase in the number of structural components required. In addition, the workload on the central control unit 2 does not increase.

### Fourth Embodiment

FIG. 8 is a block diagram illustrating the major portion of a portable device according to the fourth embodiment of the present invention.

In the description below, reference will be made to how the fourth embodiment differs from the first embodiment. In FIG. 8, the same reference numerals as used in FIG. 1 denote similar or corresponding structural elements, and a description of such elements will be omitted. For example, the central control unit 2 and the dedicated unit 3 have internal structures similar to those described with reference to FIG. 1, and a description of them will be omitted.

The portable telephone device of the fourth embodiment comprises a memory unit 6 connected to the dedicated unit 3, as in the second embodiment shown in FIG. 6. In addition, the portable telephone device of the fourth embodiment comprises a multiplexer 7, as in the third embodiment shown in FIG. 7.

With this structure, as in the second embodiment, the dedicated unit 3 can read compressed music data directly from the memory card of the memory unit 6 and executes music reproduction, without requiring the control by the central control unit 2. Simultaneous with this music reproduction processing, the dedicated unit 3 measures the volume levels of the music data, and generates vibrator intensity data (incidental processing).

As in the third embodiment, the central control unit 2 of the fourth embodiment vibrates the vibrator of the peripheral output unit 4 when the portable telephone device receives a call or generates an alarm. In other words, the vibrator 41 of the peripheral output unit 4 of the fourth embodiment can be used not only for the original purpose (i.e., the indication of an incoming call or an alarm) but also as a vibrator that vibrates in accordance with the volume levels of the music data.

The foregoing embodiments were described above, referring to the case where the portable devices are portable telephone devices. However, the present invention is not limited to this, and the portable devices may be embodied as PDAs, portable digital players, or other portable electronic devices. To be more specific, the present invention may be embodied as a portable device whose dedicated unit processes not only music data but also video data. In this case, the portable device reproduces video data and, in synchronism therewith, displays various incidental information and outputs sound.

As described above, the embodiments of the present invention do not increase the workload of the central control unit (which is a main control device) and yet attain a function of reproducing digital data (such as music data) and its incidental function of providing vibration or display in synchronism with the reproduction processing.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A portable device comprising:
a memory configured to store digital data;
a first output unit configured to provide an output in accordance with a reproduction signal obtained by subjecting the digital data to reproduction processing;
a second output unit configured to provide an output in accordance with incidental data obtained by subjecting the digital data to the reproduction processing;
a central control unit configured to execute control operations other than the reproduction processing; and
a dedicated unit configured to generate the reproduction signal and the incidental data by receiving the digital data from the memory and executing the reproduction processing with respect to the digital data, the dedicated unit supplying the reproduction signal and the incidental data to the first and second output units, respectively.

2. The portable device according to claim 1, wherein:
said digital data is music data;
said first output unit receives an acoustic signal as said reproduction signal and performs audio output in accordance with the acoustic signal; and
said dedicated unit generates the acoustic signal from the music data acquired from the memory, and supplies the generated acoustic signal to the first output unit.

3. The portable device according to claim 1, wherein:
said digital data is music data;
said second output unit receives vibration intensity data as the incidental data and provides vibration in accordance with the vibration intensity data; and
said dedicated unit measures a volume level of the music data acquired from the memory, generates vibration intensity data corresponding to the volume level, and supplies generated vibration intensity data to the second output unit.

4. The portable device according to claim 1, wherein:
said digital data is music data;
said second output unit receives display data as said incidental data and performs display output in accordance with the display data; and
said dedicated unit measures a volume level of the music data acquired from the memory, generates display data used for displaying the volume level, and supplies generated display data to the second output unit.

5. The portable device according to claim 1, wherein:
said digital data is music data;
said second output unit receives display data as said incidental data and performs display output in accordance with the display data; and
said dedicated unit measures a frequency component of the music data acquired from the memory, generates display data used for displaying the frequency component, and supplies generated display data to the second output unit.

6. The portable device according to claim 1, wherein:
said dedicated unit includes table information which associates the incidental information with characteristic data indicating characteristics of the reproduction signal; and
said dedicated unit acquires characteristic data by measuring the characteristics of the reproduction signal, acquires incidental data corresponding to the characteristic data by referring to the table information, and supplies acquired incidental data to the second output unit.

7. The portable device according to claim 1, wherein said central control unit reads the digital data from the memory and sends the digital data to the dedicated unit.

8. The portable device according to claim 1, wherein said dedicated unit reads and receives the digital data from the memory in accordance with an instruction supplied from the central control unit.

9. A portable device comprising:
a memory configured to store digital data;
a first output unit configured to provide an output in accordance with a reproduction signal obtained by subjecting the digital data to reproduction processing;
a central control unit configured to execute control operations other than the reproduction processing;
a second output unit configured to provide an output in accordance with an incidental data signal obtained by subjecting the digital data to the reproduction processing or a control signal output from the central control unit;
a dedicated unit configured to generate the reproduction signal and the incidental data signal by receiving the digital data from the memory and executing the reproduction processing with respect to the digital data, the dedicated unit supplying the reproduction signal to the first output unit; and
a selector which selects one of the incidental data signal output from the dedicated unit and the control signal supplied from the central control unit, and supplies a selected signal to the second output unit.

10. The portable device according to claim 9, wherein said selector selects the incidental data signal from the dedicated unit in accordance with a selection signal which the central control unit outputs when the reproduction processing is being executed with respect to the digital data, and supplies the selected signal to the second output unit.

11. The portable device according to claim 9, wherein:
said digital data is music data;
said first output unit receives an acoustic signal as said reproduction signal and performs audio output in accordance with the acoustic signal;
said second output unit provides a vibration output in accordance with one of the incidental data signal and the control signal;
said dedicated unit performs a music reproduction operation by generating the acoustic signal from the music data acquired from the memory and by supplying the generated acoustic signal to the first output unit, measures a volume level of the music data, and generates a vibration intensity signal corresponding to the volume level as said incidental data signal; and
said selector selects the incidental data signal from the dedicated unit in accordance with a selection signal which the central control unit outputs when the music reproduction operation is being executed, and supplies the selected signal to the second output unit.

12. The portable device according to claim 11, further comprising a radio communication unit configured to perform radio communications under control by the central control unit,
wherein the central control unit outputs the control signal for controlling an output operation when the radio communication unit performs radio communications, and the selection signal for controlling the selector, and
the selector selects the control signal in accordance with the selection signal output from the central control unit, and supplies the selected control signal to the second output unit.

13. The portable device according to claim 9, wherein:
said dedicated unit includes table information which associates the incidental data with characteristic data indicating characteristics of the reproduction signal; and
said dedicated unit acquires characteristic data by measuring the characteristics of the reproduction signal, acquires incidental data corresponding to the characteristic data by referring to the table information, converts the incidental data to the incidental data signal, and supplies the incidental data signal to the selector.

14. The portable device according to claim 9, wherein:
said central control unit reads the digital data out of the memory when the digital data is subjected to reproduction processing, and supplies readout digital data to the dedicated unit; and
the selection signal used for selecting the incidental data signal output from the dedicated unit is supplied to the selector.

15. The portable device according to claim 9, wherein:
the central control unit activates the dedicated unit when the digital data is subjected to the reproduction processing, selects the selection signal used for selecting the incidental data signal output from the dedicated unit, and supplies the selected selection signal to the selector; and
the dedicated unit reads the digital data out of the memory and executes reproduction processing with respect to the readout digital data.

16. The portable device according to claim 9, further comprising a radio communication unit that serves as a portable telephone function operating under control by the central control unit,
wherein said second output unit provides a vibration output in accordance with one of the incidental data signal and the control signal,
said central control unit outputs the control signal used for controlling a notification operation performed when an incoming signal is received;
said dedicated unit performs a music reproduction operation based on the digital data acquired from the memory, and generates the incidental data signal corresponding to the volume level in synchronism with the music reproduction; and
said selector operates in response to the selection signal output from the central control unit, selects one of the incidental data signal and the control signal, and supplies a selected signal to the second output unit, the incidental data signal being output from the dedicated unit when the music reproduction is being performed, the control signal being output from the dedicated unit when the notification operation is being performed in response to the incoming call.

17. A digital data reproducing method for use in a portable device including a memory for storing the digital data and a dedicated unit for reproducing the digital data, the method comprising:
receiving the digital data corresponding to music data from the memory in a music reproduction mode;
causing the dedicated unit to perform music reproduction processing for generating an acoustic signal from the music data; and
measuring a volume level of the music data and generating incidental data which indicates the volume level.

18. A method according to claim 17, wherein:
the portable device includes an output unit for providing vibration in accordance with the incidental data; and
the method further comprises outputting the incidental data to the output unit and providing vibration in synchronism with the music reproduction processing.

19. A method according to claim 17, wherein:
the portable device includes an output unit which provides a display output in accordance with the incidental data; and
the method further comprises outputting the incidental data to the output unit and providing the display output in synchronism with the music reproduction processing.

20. A method according to claim 17, wherein:
the portable device includes a central control unit, and an output unit which provides a vibration output in accordance with one of the incidental data and the control signal output from the central control unit, and
selecting one of the incidental data and the control data in accordance with an instruction from the central control unit and supplying selected data to the output unit, the incidental data being selected in the music reproduction mode and the control signal being selected in modes other than the music reproduction mode.
